(19) United States
(12) Patent Application Publication
(10) Pub. No.: US 2006/0112720 A1
(43) Pub. Date: Jun. 1, 2006

(54) Blow unit for a walk-in refrigerator

(76) Inventor: Brian S. Kim, Rancho Palos Verdes, CA (US)

Correspondence Address: PARK LAW FIRM, 3255 WILSHIRE BLVD, SUITE 1110, LOS ANGELES, CA, 90010, US

(21) Appl. No.: 10/998,441

(22) Filed: Nov. 29, 2004

(51) Int. Cl. F25D 17/04; H05K 7/20; F25D 17/06

(52) U.S. Cl. 62/407; 62/419

(57) ABSTRACT

A cooling air guide unit for a walk-in refrigerator includes a mounting part comprising a first mounting surface and a second mounting surface and a cooling air blowing part. The first and second mounting surface of the mounting part are tilted with respect to each other by a predetermined angle, and the cooling air blowing part is installed on the second mounting surface of the mounting part. The mounting part further includes a bottom interface surface, a first side interface surface, and a second side interface surface. The first and second mounting surface are rectangular and meet each other along an edge. The bottom interface surface, the first side interface surface, and the second side interface surface of the mounting part connect the remaining three edges of the first and second mounting surface, forming a shape of wedge. The cooling air blowing unit includes a fan and a safety grid, preferably made of plastic.

### BACKGROUND OF THE INVENTION

The present invention relates to a blow unit for a walk in refrigerator, which distributes the flow of cooling air evenly across a cooling chamber. More particularly, this invention relates to a blow unit, which subdues the mechanical oscillation. The invention also relates to a blow unit, in which the axis of rotation of a blowing fan is optimized to distribute the flow of cooling air evenly.

Conventionally, the cooling air blow unit including a fan was attached directly to the sheet metal of the cooling device or the duct from the cooling device. The direct attachment of the blow unit was a major source of undesirable mechanical oscillation in the walk in refrigerator. Since the mechanical oscillation covers a wide range of frequency, it may be a source of audible noise and a reason of loosing of mechanical parts.

Furthermore, since the cooling chamber of the walk in refrigerator is usually large and installed with some compartment dividing the cooling chamber into a couple of cells, the flow of cooling air was hindered and the cooling was not even across the cooling chamber of the walk in refrigerator. The presence of goods stacked on the floor also hinders the flow of cooling air further.

Accordingly, a need for an improved blow unit for walk in refrigerator cooling device has been present for a long time considering the walk in refrigerators are being used widely in the fields of the food industry and others. This invention is directed to solve these problems and satisfy the long-felt need.

### SUMMARY OF THE INVENTION

The present invention contrives to solve the disadvantages of the prior art.

An objective of the invention is to provide a blow unit attached to a duct from a walk in refrigerator cooling device that distributes the flow of cooling air evenly across a cooling chamber.

Another objective of the invention is to provide a blow unit that subdues the mechanical oscillation.

Still other objective of the invention is to provide a blow unit that the axis of rotation of a blowing fan is optimized to distribute the flow of cooling air evenly.

In a first embodiment of the invention, a cooling air guide unit for a walk-in refrigerator according to the invention includes a mounting part comprising a first mounting surface and a second mounting surface and a cooling air blowing part. The first mounting surface and the second mounting surface of the mounting part are tilted with respect to each other by a predetermined angle, and the cooling air blowing part is installed on the second mounting surface of the mounting part.

The mounting part further includes a bottom interface surface, a first side interface surface, and a second side interface surface. The first mounting surface and the second mounting surface are rectangular, meet each other along an edge. The first side interface surface, and the second side interface surface connect the remaining three edges of the first mounting surface and the second mounting surface.

The cooling air blowing unit includes a fan and a safety grid enclosing the fan and the second mounting surface of the mounting part. Preferably, the safety grid is made of plastic.

The first mounting surface and the second mounting surface of the mounting part form a shape of wedge.

The mounting part further includes a first mechanical fastener on the first mounting surface and a second mechanical fastener on the second mounting surface.

In a second embodiment of the invention, a refrigerating unit for walk-in refrigerator includes a cooling unit comprising an enclosure, a cooling air guide mounting surface provided on the enclosure, and a cooling air guide mounting opening provided in the cooling air guide mounting surface, a cooling air guide unit including a mounting part with a first mounting surface and a second mounting surface and a cooling air blowing part. The first mounting surface and the second mounting surface of the mounting part are tilted with respect to each other by a predetermined angle, and the cooling air blowing part is installed on the second mounting surface of the mounting part, and a mounting part for mounting the refrigerating unit to a flat surface. The cooling air guide unit is installed in the cooling air guide unit mounting opening.

The mounting part of the cooling air guide unit further includes a bottom interface surface, a first side interface surface, and a second side interface surface. The first mounting surface and the second mounting surface are rectangular, meet each other along an edge. The bottom interface surface, the first side interface surface, and the second side interface surface of the mounting part of the cooling air guide unit connect the remaining three edges of the first mounting surface and the second mounting surface of the mounting part of the cooling air guide unit.

The refrigerating unit takes in air inside of refrigerator, cools it by the transfer of a portion of the heat away from the air with a heat pump using the compression and the phase change of gas, a refrigerant, and then blows it into the refrigerator.

Although the present invention is briefly summarized, the fuller understanding of the invention can be obtained by the following drawings, detailed description and appended claims.

### BRIEF DESCRIPTION OF THE DRAWINGS

These and other features, aspects and advantages of the present invention will become better understood with reference to the accompanying drawings, wherein:

FIG. 1 is a schematic view of a walk-in refrigerator with a cooling air guide unit according to the invention installed on a cooling unit;

FIG. 2 is a perspective view of the cooling air guide unit;

FIG. 3 is a front elevational view of the cooling air guide unit installed on the cooling unit;

FIG. 4 is a side cross-sectional view of of the cooling air guide unit installed on the cooling unit;

FIG. 5 is a plan view of the cooling air guide unit; and

FIG. 6 is a cross-sectional view of the cooling air guide unit.

### DETAILED DESCRIPTION OF THE INVENTION

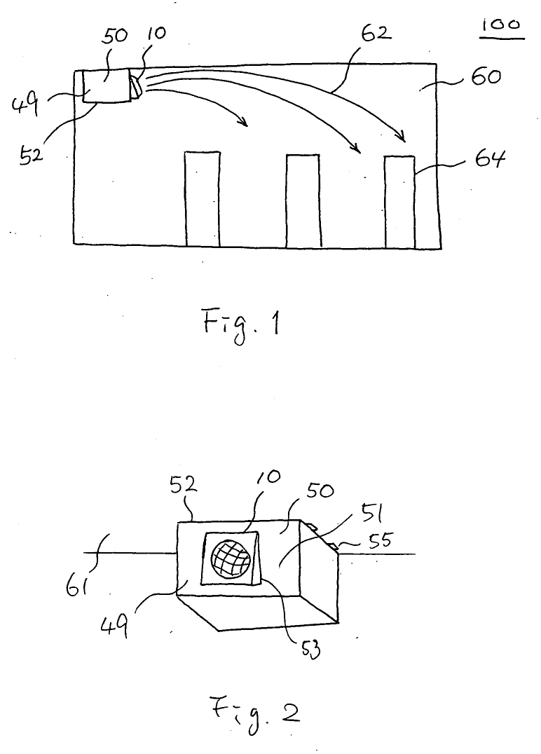

FIG. 1 shows a perspective diagram of a walk-in refrigerator 100 with a cooling air guide unit 10 according to the invention installed on a cooling unit 50.

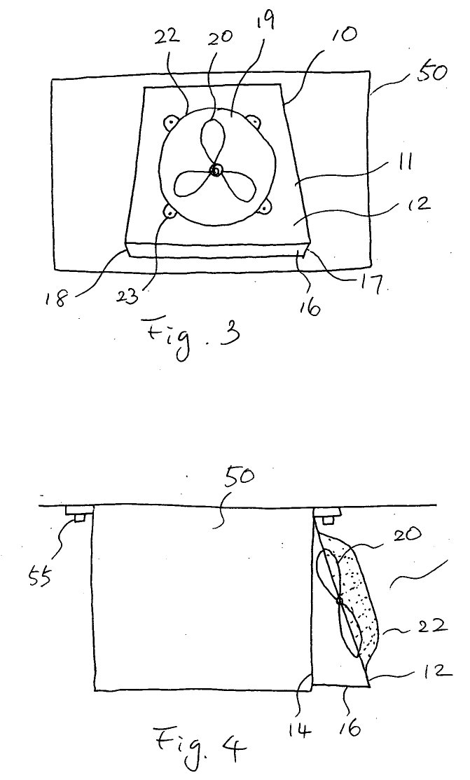

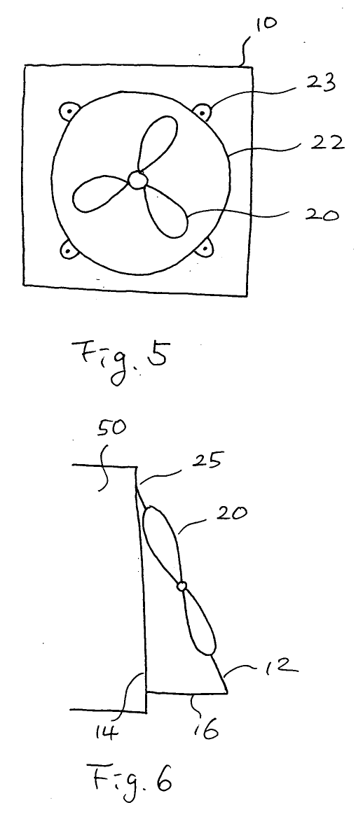

In a first embodiment of the invention shown in FIGS. 2 through 6, a cooling air guide unit 10 for the walk-in refrigerator 100 according to the invention includes a mounting part 11 including a first mounting surface 14 and a second mounting surface 12 and a cooling air blowing part 19. The first mounting surface 14 and the second mounting surface 12 of the mounting part 11 are tilted with respect to each other by a predetermined angle, and the cooling air blowing part 19 is installed on the second mounting surface 12 of the mounting part 11.

The mounting part 11 further includes a bottom interface surface 16, a first side interface surface 17, and a second side interface surface 18. The first mounting surface 14 and the second mounting surface 12 are preferably rectangular, meet each other along an edge. The bottom interface surface 16, the first side interface surface 17, and the second side interface surface 18 connect the remaining three edges of the first mounting surface 14 and the second mounting surface 12.

The cooling air blowing unit 19 includes a fan 20 and a safety grid 22 enclosing the fan 20 and the second mounting surface 12 of the mounting part 11 to protect a human worker near and the blade of the fan 20. Preferably, the safety grid 22 is made of plastic.

The first mounting surface 14 and the second mounting surface 12 of the mounting part 11 form a shape of wedge.

The mounting part 11 further includes a first mechanical fastener 25 on the first mounting surface 14 and a second mechanical fastener 23 on the second mounting surface 12. The first mechanical fastener 25 fix the first mounting surface 14 of the mounting part 11 on the cooling unit 50 and the second mechanical fastener 23 fixes the safety grid 22 on the second mounting surface 12 the mounting unit 11.

In a second embodiment of the invention shown in FIG. 1 and FIG. 2, a refrigerating unit 52 for walk-in refrigerator 100 includes a cooling unit 50 including an enclosure 49, a cooling air guide mounting surface 51 provided on the enclosure 49, and a cooling air guide mounting opening 53 provided in the cooling air guide mounting surface 51, a cooling air guide unit 10 including a mounting part 11 with a first mounting surface 14 and a second mounting surface 12 and a cooling air blowing part 19. The first mounting surface 14 and the second mounting surface 12 of the mounting part 11 are tilted with respect to each other by a predetermined angle, and the cooling air blowing part 19 is installed on the second mounting surface 12 of the mounting part 11, and a mounting part 55 for mounting the refrigerating unit 52 to a flat surface such as a ceiling 61. The cooling air guide unit 10 is installed in the cooling air guide unit mounting opening 53.

The mounting part 11 of the cooling air guide unit 10 further includes a bottom interface surface 16, a first side interface surface 17, and a second side interface surface 18. The first mounting surface 14 and the second mounting surface 12 are preferably rectangular and meet each other along an edge. The bottom interface surface 16, the first side interface surface 17, and the second side interface surface 18 of the mounting part 11 of the cooling air guide unit 10 connect the remaining three edges of the first mounting surface 14 and the second mounting surface 12 of the mounting part 11 of the cooling air guide unit 10 forming a shape of wedge.

There exist many sources of mechanical oscillation around the walk-in refrigerator 100 including a compressor in the cooling unit 50 and the fan 20. Usually the enclosure 49 is made of sheet metal, which is prone to oscillate. The mechanical oscillations can cause a unwanted resonance to build up across the whole system, loosening of mechanical parts and eventually disrupting the system.

The wedge-shaped mounting part makes the whole structure of the cooling unit 50 with the cooling air guide unit 10 resistant to mechanical oscillation.

The cooling air guide unit 10 is adapted to a cooling air producing device 50. The cooling air guide unit 10 can be adapted to a duct extended from a cooling air producing device that is installed outside of the walk-in refrigerator 100.

Because of the wedge-shaped structure, the cooling air guide unit 10 blows the cooling air 62 upward from a horizontal direction by a predetermined angle, blowing the cooling air 62 evenly across a cooling chamber 60. In an embodiment, the predetermined angle is about 5 degrees.

The refrigerating unit 52 takes in air inside of refrigerator 100, cools it by the transfer of a portion of the heat away from the air with a heat pump using the compression and the phase change of gas, a refrigerant, and then blows it into the refrigerator 100.

While the invention has been shown and described with reference to different embodiments thereof, it will be appreciated by those skilled in the art that variations in form, detail, compositions and operation may be made without departing from the spirit and scope of the invention as defined by the accompanying claims.

What is claimed is:

1. A cooling air guide unit for a walk-in refrigerator comprising;
a) a mounting part comprising a first mounting surface and a second mounting surface; and
b) a cooling air blowing part,
wherein the first mounting surface and the second mounting surface of the mounting part are tilted with respect to each other by a predetermined angle, and the cooling air blowing part is installed on the second mounting surface of the mounting part.

2. The cooling air guide unit of claim 1, wherein the mounting part further comprises a bottom interface surface, a first side interface surface, and a second side interface surface, wherein the first mounting surface and the second mounting surface are rectangular, and meet each other along an edge.

3. The cooling air guide unit of claim 2, wherein the bottom interface surface, the first side interface surface, and the second side interface surface connect the remaining three edges of the first mounting surface and the second mounting surface.

4. The cooling air guide unit of claim 1, wherein the cooling air blowing unit comprises a fan.

5. The cooling air guide unit of claim 4, wherein the cooling air blowing unit further comprises a safety grid.

6. The cooling air guide unit of claim 5, wherein the safety grid encloses the fan and the second mounting surface of the mounting part.

7. The cooling air guide unit of claim 6, wherein the safety grid is made of plastic.

8. The cooling air guide unit of claim 1, wherein the first mounting surface and the second mounting surface of the mounting part form a shape of wedge.

9. The cooling air guide unit of claim 1, wherein the mounting part further comprises a first mechanical fastener on the first mounting surface and a second mechanical fastener on the second mounting surface.

10. A refrigerating unit for walk-in refrigerator comprising:
a) a cooling unit comprising an enclosure, a cooling air guide mounting surface provided on the enclosure, and a cooling air guide mounting opening provided in the cooling air guide mounting surface;
b) a cooling air guide unit comprising a mounting part comprising a first mounting surface and a second mounting surface and a cooling air blowing part, wherein the first mounting surface and the second mounting surface of the mounting part are tilted with respect to each other by a predetermined angle, and the cooling air blowing part is installed on the second mounting surface of the mounting part; and
c) a mounting part for mounting the refrigerating unit to a flat surface,
wherein the cooling air guide unit is installed in the cooling air guide unit mounting opening.

11. The refrigerating unit of claim 10, wherein the mounting part of the cooling air guide unit further comprises a bottom interface surface, a first side interface surface, and a second side interface surface, wherein the first mounting surface and the second mounting surface are rectangular, meet each other along an edge.

12. The refrigerating unit of claim 11, wherein the bottom interface surface, the first side interface surface, and the second side interface surface of the mounting part of the cooling air guide unit connect the remaining three edges of the first mounting surface and the second mounting surface of the mounting part of the cooling air guide unit.

13. The refrigerating unit of claim 10, wherein the cooling air blowing unit of the cooling air guide unit comprises a fan.

14. The refrigerating unit of claim 13, wherein the cooling air blowing unit of the cooling air guide unit further comprises a safety grid.

15. The refrigerating unit of claim 14, wherein the safety grid encloses the fan and the second mounting surface of the mounting part of the cooling air guide unit.

16. The refrigerating unit of claim 15, wherein the safety grid is made of plastic.

17. The refrigerating unit of claim 10, wherein the first mounting surface and the second mounting surface of the mounting part of the cooling air guide unit form a shape of wedge.

18. The refrigerating unit of claim 10, wherein the mounting part of the cooling air guide unit further comprises a first mechanical fastener on the first mounting surface and a second mechanical fastener on the second mounting surface of the mounting unit of the cooling air guide unit.
